(19) United States
(12) Patent Application Publication
(10) Pub. No.: US 2024/0295827 A1
(43) Pub. Date: Sep. 5, 2024

(54) CALIBRATED MEASUREMENT OF OVERLAY ERROR USING SMALL TARGETS

(71) Applicant: KLA Corporation, Milpitas, CA (US)

(72) Inventors: Yoel Feler, Haifa (IL); Mark Ghinovker, Yoqneam Ilit (IL); Nir BenDavid, Hod Hasharon (IL); Yoram Uziel, Yodfat (IL)

(21) Appl. No.: 17/762,030

(22) PCT Filed: Mar. 4, 2022
(86) PCT No.: PCT/US22/18812

§ 371 Date: Mar. 18, 2022

Related U.S. Application Data
(60) Provisional application No. 63/299,010, filed on Jan. 13, 2022.

(51) Int. Cl. G03F 7/00

(52) U.S. Cl. CPC G03F 7/70633; G03F 7/70516; G03F 7/70625

(57) ABSTRACT

A method for semiconductor metrology includes depositing first and second film layers on a substrate, patterning the layers to define a first target including a first feature in the first layer and a second feature in the second layer adjacent to the first feature, and a second target on the substrate including a first part, which is identical to the first target, and a second part adjacent to the first part such that the second overlay target has rotational symmetry of 180° around a normal to the substrate. The method further includes capturing and processing a first image of the second target to compute a calibration function based on the first and second parts of the target, and capturing and processing a second image of the first target while applying the calibration function to estimate an overlay error between the first and second film layers at the first location.

### CROSS-REFERENCE TO RELATED APPLICATION

This application claims benefit of U.S. the Provisional Patent Application 63/299, 010, filed Jan. 13, 2022, which is incorporated herein by reference.

### FIELD OF THE INVENTION

The present invention relates generally to manufacture of semiconductor devices, and particularly to methods and target features for semiconductor circuit metrology.

### BACKGROUND

Semiconductor circuits are commonly manufactured using photolithographic methods. In photolithography, a thin layer of a photosensitive polymer (photoresist) is deposited over a semiconductor substrate and patterned using optical or other radiation, leaving parts of the substrate covered by the photoresist. The photoresist is patterned by a scanner projecting an image of a reticle onto the photoresist, typically using ultraviolet radiation. After patterning, the substrate is modified by methods such as etching and ion bombardment to change the material properties and/or the topography of the substrate, while the parts of the substrate covered by the photoresist are not affected.

Semiconductor circuit metrology is used for measuring properties of the patterned photoresist, such as the topography and location of the patterned features. Accurate location of the patterned features of the photoresist with respect to previously patterned process layers is crucial for achieving a high yield of the photolithographic process. Any error in the registration (misregistration) of the patterned photoresist with respect to an underlying process layer is referred to as “overlay error.” As an example, in typical semiconductor circuits with minimum line-widths of 10-14 nm (so-called 10-nm design rule), the maximal permissible overlay error is 2-3 nm. In leading-edge semiconductor circuits, the line-widths are shrinking to 5 nm, with a concomitant reduction in maximal permissible overlay error.

Overlay error is commonly measured using optical overlay metrology apparatuses (commonly called optical overlay metrology tools), as optical radiation in the visible and infrared wavelengths is capable of penetrating through the photoresist layer, as well as through dielectric layers under the photoresist. Furthermore, infrared wavelengths are capable of penetrating a semiconductor substrate, such as silicon, enabling metrology through the substrate. The overlay error is measured from overlay targets located in the scribe lines of the semiconductor substrate (the lines separating adjacent dies) and/or within the dies.

Commonly used overlay metrology tools fall into one of two categories: scatterometry tools and imaging tools. Scatterometry tools, such as the ATL100™ tool by KLA Corporation (Milpitas, CA, USA), capture a diffracted (scatterometric) image of periodic target features of the overlay target from the exit pupil of the objective lens of the metrology tool. The scatterometric image, indicative of the angular distribution of the optical radiation that is scattered from the target features, is processed in order to measure the overlay error.

Imaging tools, such as the Archer™-series tools by KLA Corporation (Milpitas, CA, USA), image an overlay target, such as AIM™ overlay target by KLA. An image analysis algorithm is applied to the acquired images in order to locate the center of symmetry of the target features in the process layer and the center of symmetry of the target features in the photoresist layer. The overlay error is computed based on the displacement between the centers of symmetry of the target features in the two layers.

The terms “optical radiation” and “light,” as used in the present description and in the claims, refer generally to any and all of visible, infrared, and ultraviolet radiation.

### SUMMARY

Embodiments of the present invention that are described hereinbelow provide improved methods and systems for metrology using overlay targets, as well as targets for use in such methods.

There is therefore provided, in accordance with an embodiment of the invention, a method for semiconductor metrology. The method includes depositing a first film layer on a semiconductor substrate and a second film layer overlying the first film layer, and patterning the first and second film layers to define a first overlay target and a second overlay target. The first overlay target is disposed in a first location on the semiconductor substrate and includes a first target feature formed in the first film layer and a second target feature formed in the second film layer in a position adjacent to the first target feature. The second overlay target is disposed in a second location on the semiconductor substrate and includes a first part, which is identical to the first overlay target, and a second part, which is disposed adjacent to the first part such that the second overlay target has rotational symmetry of 180° around a normal to the semiconductor substrate. The method further includes capturing a first image, using an imaging assembly, of the second overlay target, processing the first image to compute a target calibration function based on both the first and second parts of the second overlay target, capturing a second image, using the imaging assembly, of the first overlay target, and processing the second image while applying the target calibration function to estimate an overlay error between the patterning of the first and second film layers at the first location.

In some embodiments, the second part of the second overlay target includes a rotated copy of the first part.

In additional embodiments, the first overlay target is one of a plurality of first overlay targets, each including the first and second target features, disposed at different, respective locations on the semiconductor substrate, and processing the second image includes applying the target calibration function to each of the first overlay targets.

In further embodiments, processing the first image includes using both the first and second parts of the second overlay target in the first image to estimate a first overlay error between the patterning of the first and second film layers, using only the first part of the second overlay target to estimate a second overlay error between the patterning of the first and second film layers, and computing the target calibration function responsively to a difference between the first and the second overlay errors.

In yet further embodiments, using both the first and second parts includes estimating the first overlay error by finding a displacement between respective first centers of symmetry of the first target features and the second target features in both the first and second parts of the second overlay target, and using only the first part includes estimating the second overlay error by finding a displacement between respective second centers of symmetry of the first target features and the second target features in only the first part of the second overlay target.

In some embodiments, the first image is captured in a first orientation of the semiconductor substrate, and the method includes capturing a third image of the second overlay target in a second orientation of the semiconductor substrate, which is rotated by 180° about a normal to the substrate relative to the first orientation, and processing the first image includes processing both the first and third images to estimate respective first and second overlay errors in the first and second orientations, and computing the target calibration function based on the first and second overlay errors.

In additional embodiments, the semiconductor substrate includes dies separated by scribe lines, and the first overlay target is disposed in a device area of a die and the second overlay target is disposed in a scribe line.

In further embodiments, the first target feature includes a first linear grating oriented along a first direction in the first film layer, and the second target feature includes a second linear grating oriented in the first direction in the second film layer.

In additional embodiments, the first target feature further includes a third linear grating oriented along a second direction, which is not parallel to the first direction, in the first film layer, and the second target feature includes a fourth linear grating oriented in the second direction in the second film layer.

In some embodiments, the method includes measuring an angular misalignment of the semiconductor substrate, wherein applying the target calibration function includes correcting for the angular misalignment in estimating the overlay error.

In additional embodiments, the first overlay target is one of a plurality of first overlay targets disposed at different, respective locations on the semiconductor substrate, and measuring the angular misalignment includes estimating and compensating for a local angular misalignment at each of the different locations.

There is also provided, in accordance with an embodiment of the invention, a product, which includes a semiconductor substrate and first and second film layers, which are disposed on the substrate with the second film layer overlying the first film layer. The first and second film layers are patterned to define a first overlay target and a second overlay target. The first overlay target is disposed in a first location on the semiconductor substrate and includes a first target feature formed in the first film layer and a second target feature formed in the second film layer in a position adjacent to the first target feature. The second overlay target is disposed in a second location on the semiconductor substrate and includes a first part, which is identical to the first overlay target, and a second part, which is disposed adjacent to the first part such that the second overlay target has rotational symmetry of 180° around a normal to the semiconductor substrate.

There is further provided, in accordance with an embodiment of the invention, an apparatus for semiconductor metrology. The apparatus includes an imaging assembly, which is configured to capture images of a semiconductor substrate on which first and second film layers are disposed, with the second film layer overlying the first film layer. The first and second film layers are patterned to define a first overlay target and a second overlay target. The first overlay target is disposed in a first location on the semiconductor substrate and includes a first target feature formed in the first film layer and a second target feature formed in the second film layer in a position adjacent to the first target feature. The second overlay target is disposed in a second location on the semiconductor substrate and includes a first part, which is identical to the first overlay target, and a second part, which is disposed adjacent to the first part such that the second overlay target has rotational symmetry of 180° around a normal to the semiconductor substrate. The apparatus further includes a processor, which is configured to process a first image captured by the imaging assembly of the second overlay target to compute a target calibration function based on both the first and second parts of the second overlay target, and to process a second image captured by the imaging assembly of the first overlay target while applying the target calibration function to estimate an overlay error between the patterning of the first and second film layers at the first location.

The present invention will be more fully understood from the following detailed description of the embodiments thereof, taken together with the drawings in which:

### BRIEF DESCRIPTION OF THE DRAWINGS

FIG. 1 is a schematic side view of an imaging overlay metrology apparatus for measuring overlay error on a semiconductor wafer, in accordance with an embodiment of the invention;

FIGS. 2A and 2B are schematic representations of half-targets for overlay error metrology, in accordance with embodiments of the invention;

FIGS. 3A and 3B are schematic representations of half-targets for overlay error metrology, in accordance with embodiments of the invention;

FIG. 4 is a schematic representation of a half-target for overlay error metrology, illustrating a method for correction of angular misalignment of the half-target, in accordance with an embodiment of the invention;

FIGS. 5A and 5B are schematic representations of full targets for overlay metrology, in accordance with embodiments of the invention;

FIG. 6 is a flowchart that schematically illustrates a method for calibrating measurements of overlay error, in accordance with an embodiment of the invention; and

### DETAILED DESCRIPTION OF EMBODIMENTS

### Overview

Overlay targets for overlay metrology are commonly used for precise and accurate measurements of the overlay error between successive patterned layers on a semiconductor substrate. These layers may comprise, for example, a process layer and a photoresist layer (photoresist), or, in after-etch applications, two process layers. Thus, although some example embodiments are described below with reference to a process layer and a photoresist layer, the principles of these embodiments may be applied, mutatis mutandis, to a first process layer and a second process layer. In some multiple patterning applications, the first and second process layers may comprise the same material. In some multilayer applications, the layers in which the target features of an overlay target are formed may comprise more than two layers.

Commonly used imaging overlay targets have typical dimensions of 20 μm×20 μm. Due their relatively large size, they cannot be located within the functional device area of the semiconductor circuits formed on the dies defined on a substrate, but are rather located in the scribe lines separating adjacent dies. In embodiments of the present invention, to measure the overlay error within the device area, smaller targets may be placed in this area. These smaller targets are referred to herein as “half-targets”, because they comprise only a subset of the target features of the full overlay targets in the scribe lines.

However, a single overlay measurement using a half-target may suffer from metrology errors due to at least the following three error sources: 1) angular misalignment of the half-target with respect to the Cartesian coordinates in which the overlay error is expressed, 2) aberrations of the optics of the overlay metrology tool, and 3) uncertainty regarding the actual optical magnification of the overlay tool. As the half-targets do not possess 180° rotational symmetry (in contrast to the full targets) , calibration of the metrology errors of these half-targets, which is commonly performed on full targets by measuring the target at two rotational orientations 180° apart, is not feasible.

The embodiments described hereinbelow address the problem of calibrating the metrology errors of half-targets using full targets on the same substrate. Each such full target comprises a half-target and is complemented by an additional target structure so that the full target is symmetrical over a 180° rotation. In one embodiment, such a full target comprises a half target together with a copy of the half target, wherein the copy is rotated around a normal to the substrate by 180° with respect to the non-rotated half-target. In alternative embodiments, the additional target structure may be different from the half-target.

To derive the parameters of a calibration function for the half-targets, overlay error is measured from a full target in two ways:
1) A first overlay error is measured using the entire full target. This first overlay error can be measured, for example, by having the full target in two rotational orientations 180° apart, and computing a so-called TIS-corrected overlay error as will be detailed hereinbelow; and
2) A second overlay error is measured using one of the half-targets forming the full target.
   A target calibration function is then computed (i.e., the parameters of the function are calculated) as the difference between the first overlay error and the second overlay error. The target calibration function is subsequently used to correct the overlay errors measured from the half-targets located in the device area.

In additional embodiments, a measured angular misalignment of the substrate is used for correcting for angular misalignment of the overlay target, as an additional correction to the overlay target calibration function described hereinabove. Alternatively, this technique for correction of angular misalignment may be used independently of the overlay target calibration function.

In the disclosed examples, a method for semiconductor metrology comprises depositing a first film layer on a semiconductor substrate and a second film layer overlying the first film layer. The first and second film layers are patterned to define a half-target in a first location on the semiconductor substrate (for example in the device area) and a full target in a second location (for example in the scribe line). The half-target comprises a first target feature formed in the first film layer and a second target feature formed in the second film layer in a position adjacent to the first target feature. In some embodiments, the full target comprises a first part, which is identical to the half-target, and a second part, which comprises a rotated copy of the first part. The second part is disposed adjacent to the first part such that the full target has rotational symmetry of 180° around a normal to the semiconductor substrate. Alternatively, other full target designs may be used as long as they contain the half-target and have rotational symmetry of 180° around the normal.

An imaging assembly captures images of the half and full targets. The image of the full target is processed to compute a target calibration function based on both the first and second parts of the full target. The image of the half-target is processed, while applying the target calibration function, to estimate the overlay error between the patterning of the first and second film layers at the location of the half-target.

Overlay Metrology Apparatus

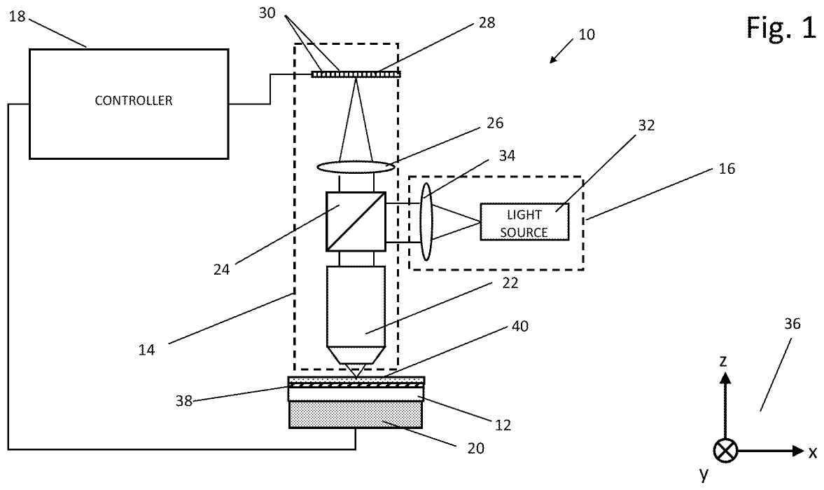

FIG. 1 is a schematic side view of an imaging overlay metrology apparatus 10 for measuring overlay error on a semiconductor wafer 12, in accordance with an embodiment of the invention. Apparatus 10 is shown by way of example, to illustrate the use of the overlay targets and the calibration methods that are described herein. Alternatively, such targets may be used in other sorts of overlay metrology systems.

Imaging overlay metrology apparatus 10 comprises an imaging assembly 14, an illumination assembly 16, a controller 18, and a table 20 on which wafer 12 is mounted. Imaging assembly 14 comprises an objective lens 22, a cube beamsplitter 24, and an imaging lens 26. Imaging assembly 14 further comprises a two-dimensional sensor array 28, comprising for example, a complementary metal-oxide- semiconductor (CMOS) detector with a two-dimensional array of pixels 30. Imaging lens 26 images the top surface of wafer 12 onto sensor array 28.

Illumination assembly 16 comprises a light source 32, emitting optical radiation, and a lens 34. Table 20 is located in proximity to objective lens 22, and comprises actuators, controlled by controller 18, which can move the table linearly in the x-, y-, and z-directions (with reference to Cartesian coordinates 36), as well as rotate the table around the z-axis.

In the pictured embodiment, a first film layer 38 has been deposited over semiconductor wafer 12 and patterned in a photolithographic process. In a subsequent process step, a second film layer 40, comprising photoresist, has been deposited over first film layer 38. In the present embodiment, first film layer 38 is referred to as a “process layer, ” and second film layer 40 is referred to as a “photoresist layer.” In alternative embodiments, such as after-etch applications, both the first and second film layers may comprise process layers. Layers 38 and 40 comprise patterns of semiconductor circuits, as well as of overlay targets, formed by a photolithographic process.

Controller 18 is coupled to sensor array 28 and to table 20. Controller 18 typically comprises a programmable processor, which is programmed in software and/or firmware to carry out the functions that are described herein, along with suitable digital and/or analog interfaces for connection to the other elements of apparatus 10. Alternatively or additionally, controller 18 comprises hard-wired and/or programmable hardware logic circuits, which carry out at least some of the functions of the controller. Although controller 18 is shown in FIG. 1, for the sake of simplicity, as a single, monolithic functional block, in practice the controller may comprise multiple, interconnected control units, with suitable interfaces for receiving and outputting the signals that are illustrated in the figures and are described in the text.

To capture an image of an overlay target in film layers 38 and 40, wafer 12 is positioned on table 20 so that the target is in the field of view (FOV) of objective lens 22. Light source 32 projects a beam of optical radiation to lens 34, which further projects the beam to cube beamsplitter 24. Beamsplitter 24 reflects the beam into objective lens 22, which projects the beam onto wafer 12 illuminating the overlay target. The radiation impinging on wafer 12 is reflected back to objective lens 22, and further imaged by lens 26 onto sensor array 28. Controller 18 captures the image and processes it in order to measure the overlay error.

Half-Targets

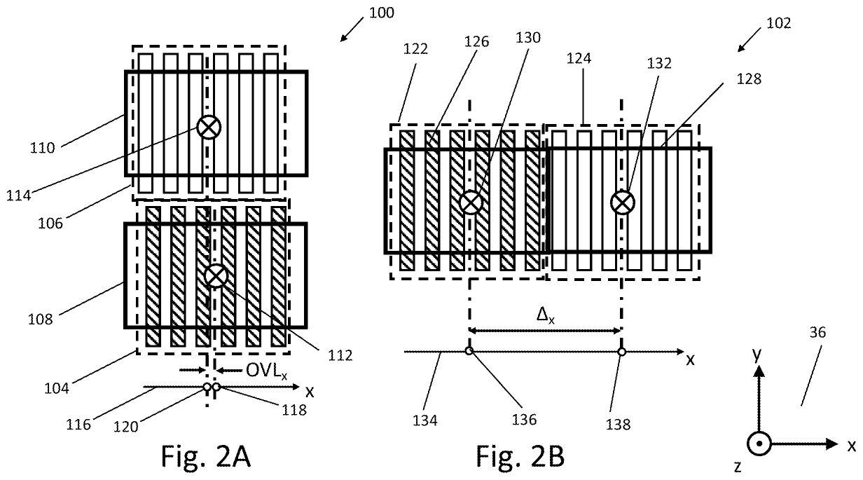

FIGS. 2A and 2B are schematic representations of two half-targets 100 and 102, respectively, which are formed on a semiconductor substrate for overlay error metrology in one dimension, in accordance with an embodiment of the invention. Both half-targets 100 and 102 are used for measuring overlay error in the x-direction, as indicated by coordinate axes 36. (The labeling of the axes is arbitrary.)

Half-target 100 comprises a process grating 104 as a first target feature, formed in process layer 38, and a photoresist grating 106 as a second target feature, formed in photoresist layer 40. Each grating comprises six parallel, equispaced and equal-width bars oriented in the y-direction. In the pictured example, the photoresist grating is located above the process grating (i.e., in the positive direction along the y-axis). Because this arrangement is non-symmetrical, other, similar half-targets (not shown) may be formed on the semiconductor substrate with the process grating above the photoresist grating.

In an ideal lithographic process, the bars of the two gratings 104 and 106 will be aligned with each other in the x-direction, corresponding to a nominal x-overlay error of zero. (In the present description, the term “nominal” refers to the dimensions and patterns that would be printed in an ideal lithographic process, in accordance with the design of the masks used to pattern the two film layers.) However, due to process and lithography errors, gratings 104 and 106 are shifted with respect to each other in the x-direction by the amount of the x-overlay error, labeled OVLₓ. (For the sake of clarity, the shift between process grating 104 and photoresist grating 106 has been exaggerated in the figure.)

For measuring the overlay error in the x-direction using half-target 100, two regions of interest (ROI) 108 and 110 are defined over process grating 104 and photoresist grating 106, respectively. (Although ROIs 108 and 110 are shown in the figures as encompassing the entire half-targets, smaller ROIs, containing only parts of the half-targets, may alternatively be used.) Half-target 100 is imaged onto sensor array 28 (FIG. 1), and controller 18 processes the portions of the image within ROIs 108 and 110. Based on ROI 108, controller 18 computes the position of a center of symmetry 112 of process grating 104; and based on ROI 110, the controller similarly computes the position of a center of symmetry 114 of photoresist grating 106. (The positions of centers of symmetry 112 and 114 in the x-direction are determined by the centers of symmetry of the respective gratings 104 and 106, and in y-direction by the respective positions in the y-direction of ROIs 108 and 110.) Centers of symmetry 112 and 114 are projected to respective projections 118 and 120 on an x-axis 116, and the overlay error in the x-direction, OVLₓ, is computed as the distance between the two projections.

Similarly to half-target 100, half-target 102 comprises a process grating 122 as a first target feature, formed in process layer 38, and a photoresist grating 124 as a second target feature, formed in photoresist layer 40, with each grating comprising six parallel bars. However, gratings 122 and 124 are positioned side-by-side in the x-direction, rather than in the y-direction as in half-target 100. For measuring the overlay error in the x-direction using half-target 102, two ROIs 126 and 128 are defined over process grating 122 and photoresist grating 124, respectively. Again similarly to half-target 100, positions of centers of symmetry 130 and 132 are computed by controller 18 from a captured image of half-target 102, and projected onto an x-axis 134 to respective projections 136 and 138 with a spacing Δₓ. However, unlike the spacing between projections 118 and 120 for half-target 100, spacing Δₓ is a sum of the nominal x-distance D_{nominal,x} between centers of symmetry 130 and 132 and the overlay error OVLₓ: Δₓ=D_{nominal,x}+OVLₓ. Thus, the overlay error is computed by subtracting D_{nominal,x} from the measured spacing Δₓ: OVLₓ=Δₓ−D_{nominal,x}.

For measuring the overlay error in the y-direction, half-targets similar to half-targets 100 and 102 may be used with a 90° rotation of these targets.

Although half-targets 100 and 102 are shown in the figures as comprising gratings of six parallel bars, in alternative embodiments gratings with fewer or more bars may be used. In yet other embodiments, the first target feature in process layer 38 and the second target feature in photoresist layer 40 may comprise any other pattern satisfying the following conditions of symmetry: A target feature used for measuring x-overlay error should have reflection symmetry about the y-axis, and a target feature used for measuring y-overlay error should have reflection symmetry about the x-axis. Alternatively, one or each of these target features should by symmetrical around a 180° rotation around the z-axis. Moreover, the first and second target features may differ from each other, as long as the above symmetry conditions are satisfied.

Alternatively, the half-targets may comprise Moiré-targets, wherein each of the first and second target features comprises a linear photoresist grating overlaid on a process grating. For each target feature, the two gratings have a slightly differing spatial frequencies, so that the captured image has a spatial frequency equal to the difference between the grating frequencies. By designing the two target features to have spatial frequency differences that are equal in magnitude but with opposite signs, controller 18 can process the captured images of the first and second target features to estimate the overlay error between process layer 38 and photoresist layer 40.

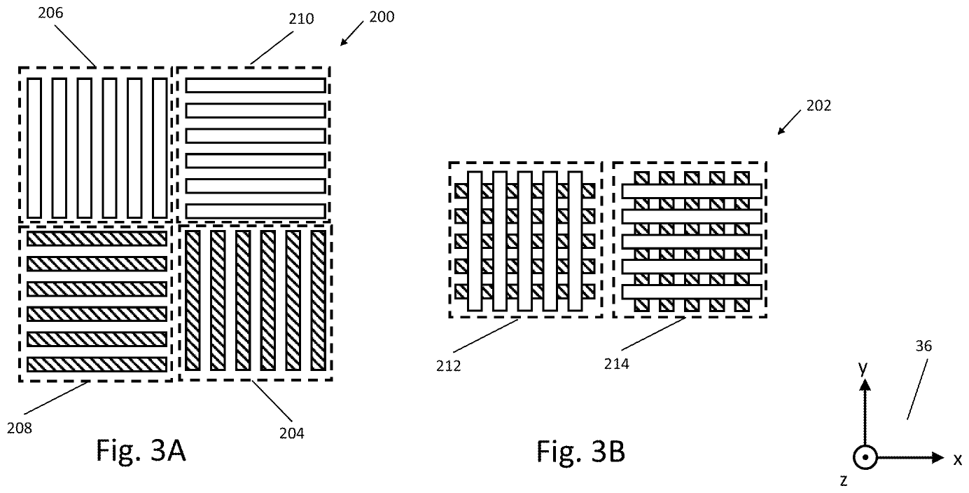

FIGS. 3A and 3B are schematic representations of two half-targets 200 and 202, respectively, for overlay error metrology in two dimensions, in accordance with further embodiments of the invention.

Half-target 200 comprises four target features 204, 206, 208, and 210. Each of target features 204 and 206 comprises six parallel bars oriented in the y-direction, similar to target features 122 and 124 of half-target 102 (FIG. 2B), and formed respectively in process layer 38 and photoresist layer 40. Target features 208 and 210, formed respectively in process layer 38 and photoresist layer 40, are similar to target features 204 and 206, but oriented in the x-direction. Alternatively, the target features used for measuring the overlay in the x- and y-directions may refer to two different process layers. For example, target feature 208 may be formed in process layer 38, while target feature 204 may be formed in a different process layer. Both x- and y-overlay errors OVLₓ and OVL_{y} may be estimated by controller 18 from a captured image of half-target 200 using the methods described hereinabove with reference to FIG. 2B.

Although the bars of target features 204, 206, 208, and 210 are aligned in the figure along the Cartesian x-and y-axes, in an alternative embodiment this alignment may be relaxed. For example, the bars of target features 208 and 210 may be oriented in another direction, as long as this direction is not parallel with the y-direction.

Half-target 202 comprises target features 212 and 214, wherein each target feature comprises two target features of half-target 200 in an overlaid “hatched” configuration. Thus, target feature 212 comprises target features 206 and 208 from half-target 200, and target feature 214 comprises target features 204 and 210. For estimating x- and y-overlay errors from half-target 202, controller 18 identifies the bars in the two orthogonal directions in the captured images of each of target features 212 and 214, and then use the methods described hereinabove.

Similarly to FIG. 3A, the bars in target features 212 and 214 are shown as being oriented in two perpendicular directions. In an alternative embodiment this alignment may be relaxed. For example, the bars that in FIG. 3B are oriented in the x-direction may be oriented in another direction, as long as this direction is not parallel with the y-direction.

Error Sources for Half-Targets 100 And 102

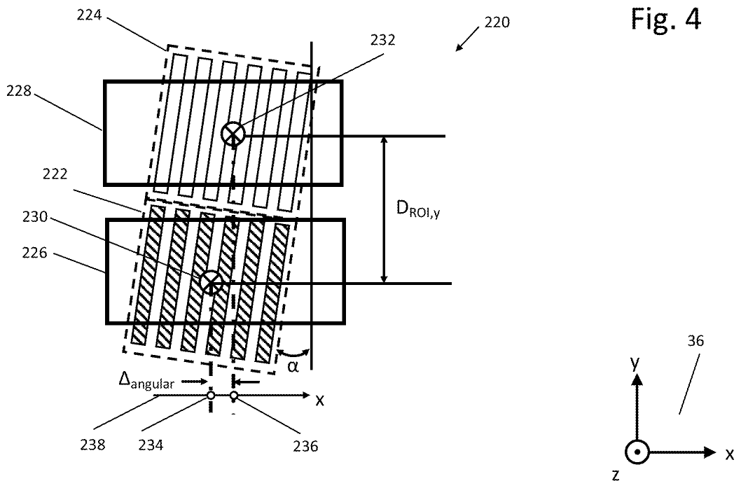

FIG. 4 is a schematic representation of a half-target 220, illustrating an error Δ_{angular} of overlay error measurement due to angular misalignment, which is corrected in accordance with an embodiment of the invention.

Half-target 220 is similar to half-target 100 (FIG. 2A), comprising a process grating 222 and a photoresist grating 224. In order to emphasize the error due to the angular misalignment, gratings 222 and 224 are aligned with each other with zero overlay error, i.e., were the x-overlay error measured in the absence of an angular misalignment, the result would be OVLₓ=0. Half-target 220 is misaligned with respect to Cartesian coordinates 36 by an angular misalignment of a. (For the sake of clarity, the angle is exaggerated in the figure. However, small-angle approximations are used hereinbelow in determining its effect, as angular misalignments in optical overlay metrology systems, such as apparatus 10, are typically very small.)

Similarly to measuring overlay error using half-target 100, two ROIs 226 and 228 are defined over process grating 222 and photoresist grating 224, respectively. Controller 18 captures images of gratings 222 and 224 within ROIs 226 and 228, and computes respective centers of symmetry 230 and 232. Centers of symmetry 230 and 232 are projected (in Cartesian coordinates 36) to respective projections 234 and 236 on an x-axis 238, wherein the distance between these two projections, Δ_{angular}, is due entirely to the angular misalignment α of half-target 220. Were the distance between projections 234 and 236 taken as the measured x-overlay error OVLₓ, this result would be in error by the amount of Δ_{angular}.

The error Δ_{angular}, due to pivoting of centers of symmetry 230 and 232 along the x-direction, may be computed as Δ_{angular}=α×D_{ROI,y}, where D_{ROI,y} is the separation between centers of symmetry 230 and 232 in the y-direction, i.e., the separation between the centers of the two ROIs 226 and 228. (As angular misalignments of this sort are usually very small, such as a few milliradians, small-angle approximations are used in the description.) For example, using values of D_{ROI,y}=5 μm and α=1 mrad leads to an error of A_{angular}=5 nm.

Similar errors, due to angular misalignment, will affect the measured overlay errors when using two-dimensional half-targets, such as half-target 200 (FIG. 3A). However, half-targets for which the pivoting of the centers of symmetry is in a direction perpendicular to the measured overlay error, such as half-target 102 (FIG. 2B) , do not suffer from small angular misalignments to any appreciable degree.

Optical aberrations of the overlay metrology tool may lead to a shift of the bars of gratings 104 and/or 106 of half-target 100 in the x-direction, potentially even in mutually opposite directions. The aberrations may consequently affect the measured displacements of the gratings in the x-direction, and thus the measured x-overlay error. A similar shift of the bars of gratings 122 and/or 124 of half-target 102 may affect the measured displacements of the gratings.

An uncertainty of the actual optical magnification M of the overlay metrology tool by AM may lead to an error Δ_{Mag} for the nominal x-distance D_{nominal,x} between centers of symmetry 130 and 132 in half-target. 102 (FIG. 2B). The error may be computed as Δ_{mag}=(ΔM/M)×D_{nominal,x}. This error propagates directly to OVLₓ, which is computed as a difference between Δₓ and D_{nominal,x}. For example, a nominal value of D_{nominal,x}=5 μm and a relative error ΔM/M of 10⁻³ for the magnification lead to an error Δ_{Mag}=5 nm.

Similar errors due to uncertainty of the actual optical magnification M may be experienced when using two-dimensional half-targets, such as half-target 200 (FIG. 3A). However, for half-targets, such as half-target 100 (FIG. 2A), wherein the nominal separation of centers of symmetry 112 and 114 is zero in the direction of the overlay error measurement, the uncertainty of optical magnification does not lead to any appreciable error.

### Full Targets

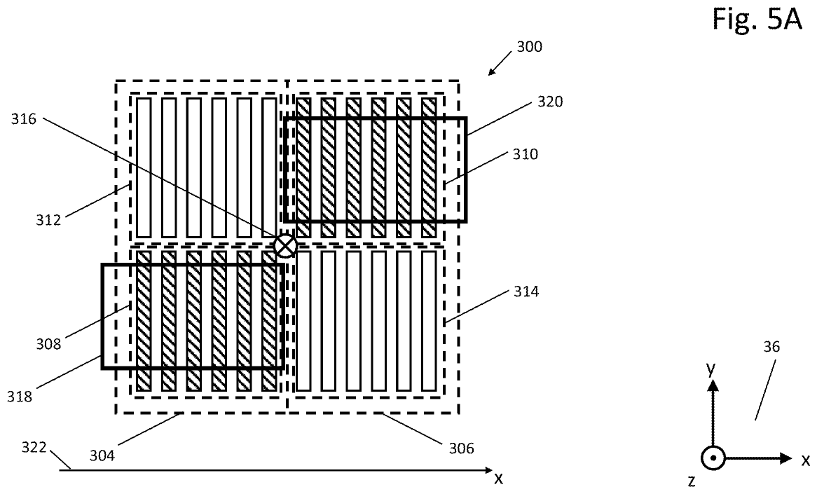

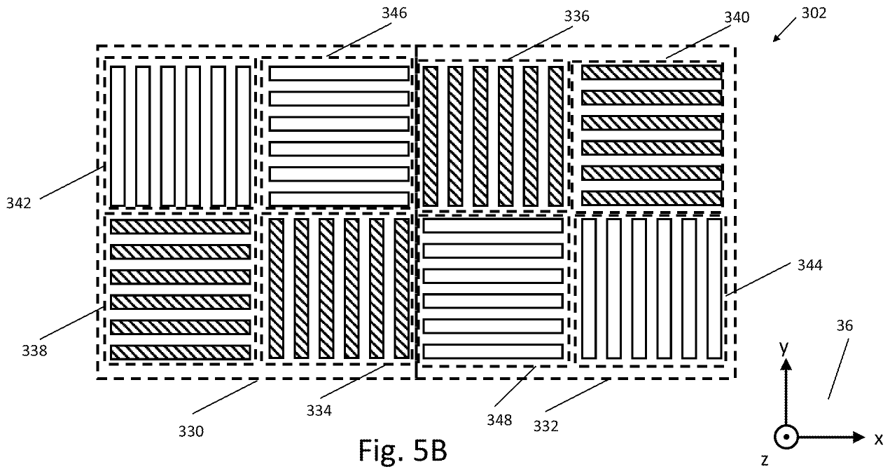

FIGS. 5A and 5B are schematic representations full targets 300 and 302 formed from half-targets 100 (FIG. 2A) and 200 (FIG. 3A), respectively, in accordance with embodiments of the invention. In the described embodiment, full targets are formed by joining a half-target with its copy that is rotated by 180° around a normal to semiconductor substrate 12 (FIG. 1). Thus, full targets are symmetrical with respect to rotation by 180° around the normal to semiconductor substrate 12. Alternatively, as described hereinabove, other designs may be used for a full target.

The rotational symmetry of full targets 300 and 302 makes it possible for apparatus 10 to measure the overlay error accurately by capturing and processing images of the target at relative rotations of 0° and 180°. This method enables the tool-induced shift (TIS), due to inaccuracies in the metrology apparatus, to be calibrated and thus separated from the actual overlay error. Thus, the term “accurate” is used in the present description to refer to TIS-calibrated overlay measurements.

As will be detailed below, full target 300 may be used to measure the x-overlay error accurately, as well as to calibrate the x-overlay error measured using half-target 100. Full target 302 may be used to measure the overlay error accurately in both x and y-directions, as well as to calibrate x- and y-overlay errors measured using half-target 200.

Calibrating Half-Target 100 Using Full Target 300

Full target 300 comprises a first part 304 and a second part 306, wherein the first part is identical to half-target 100 and the second part is a copy of half-target 100 rotated by 180° around the normal to substrate 12 (around the z-axis). Full target 300 thus comprises a first target pattern formed by process layer gratings 308 and 310 and a second target pattern formed by photoresist layer gratings 312 and 314.

Using full target 300, x-overlay error is measured independently in two orientations of semiconductor substrate 12 that are 180° apart. In the first orientation, referred to as the 0°-orientation, an x-overlay error OVL_{x,0} is measured. To measure the position of a first center of symmetry 316 of the first target pattern, two ROIs 318 and 320 are defined over respective process layer gratings 308 and 310 in an image of full target 300 captured by apparatus 10 (FIG. 1). Controller 18 processes the parts of the image within ROIs 318 and 320 to determine the position of center of symmetry 316 by, for example, projecting the contents of the ROIs onto an x-axis 322.

Controller 18 similarly finds the position of a second center of symmetry for the second target pattern by processing the image within two ROIs positioned over photoresist gratings 312 and 314. (For the sake of simplicity, the second center of symmetry and the corresponding ROIS are omitted from the figure.) Controller 18 estimates OVL_{x,0} as the separation between first and second centers of symmetry.

After a 180° rotation of semiconductor substrate 12 around its normal, an x-overlay error OVL_{x,180} is measured using the same method as for measuring OVL_{x,0}. Controller 18 computes an accurate x-overlay error OVL_{x,ACC} as half of the difference between the x-overlay errors measured in the two substrate orientations: OVL_{x,ACC}=(OVL_{x,0}−OVL_{x,180})/2.

Alternatively, the measurement of the overlay error in 180° orientation may be omitted, and the overlay error OVL_{x,0} may be used as OVL_{x,ACC} in the computations hereinbelow.

To calibrate half-target 100 (as shown in FIG. 2A) , an x-overlay error OVL_{x,HT} is measured using only first part 304, which is identical to half-target 100. Thus, the method that was described above with reference to FIG. 2A is used to measure x-overlay error OVLₓ for half-target 100. A target calibration function Δ_{CAL,x} is computed by controller 18 as Δ_{CAL,x}=OVL_{x,ACC}−OVLₓ, and is used for calibrating all x-overlay errors measured using half-targets 100 at other locations, such as locations within the device areas of the dies on semiconductor substrate 12. The target calibration function Δ_{CAL,x} may be computed by controller 18 in the beginning of the overlay error metrology process, and subsequently applied to all overlay errors as they are measured. Alternatively, the target calibration function Δ_{CAL,x} may be computed independently of the sequence of overlay error measurements, and applied to the measured overlay errors at the end of the sequence.

A calibration for measuring y-overlay error using one-dimensional half-targets is done in a similar way.

### Calibrating Half-Target 200 Using Full Target 302

Full target 302 (FIG. 5B) comprises a first part 330 and a second part 332, wherein the first part is identical to half-target 200 (FIG. 3A) and the second part is a copy of half-target 200 rotated by 180° around the z-axis. A first target pattern of full target 302 is formed by process layer gratings 334 and 336, oriented in the y-direction, and 338 and 340, oriented in the x-direction. A second target pattern is formed by photoresist layer gratings 342 and 344, oriented in the y-direction, and 346 and 348, oriented in the x-direction.

Using full target 302, both x- and y-overlay errors are measured in two orientations of semiconductor substrate that are 180° apart. In the first, 0°-orientation, overlay errors OVL_{x,0} and OVL_{y,0} are measured. In the second, 180°-orientation, overlay errors OVL_{x,180} and OVL_{y,180} are measured. The overlay errors are measured in the manner described above with reference to full target 300, with x-overlay measurements using gratings 334, 336, 342, and 344, and y-overlay measurements using gratings 338, 340, 346, and 348. Accurate overlay errors are computed similarly to OVL_{x,ACC} hereinabove:
OVL_{x,ACC}=(OVL_{x,0}−OVL_{x,180})/2
OVL_{y,ACC}=(OVL_{y,0}−OVL_{y,180})/2.

For calibrating overlay error measurements using half-target 200, x- and y-overlay errors OVL_{x,HT} and OVL_{y,HT} are measured using only first part 330, which is identical to half-target 200. Thus, the same method is used as that used to measure x- and y-overlay errors OVLₓ, and OVL_{y} for half-target 200 in FIG. 3A. A two-component target calibration function (Δ_{CAL,x}, Δ_{CAL,y}) is computed by controller 18 as Δ_{CAL,x}=OVL_{x,ACC}-OVLₓ and Δ_{CAL,y}=OVL_{y,ACC}−OVL_{y}, and is used for calibrating all x- and y-overlay errors measured using half-targets 200 on semiconductor substrate 12.

Similarly to the calibration of half-target 100 using full target 300, described hereinabove, the two-component target calibration function (Δ_{CAL,x}, Δ_{CAL,y}) may be either computed by controller 18 in the beginning of the overlay error metrology process and applied to overlay errors as they are measured, or it may be computed independently of the sequence of overlay error measurements, and applied to the measured overlay errors at the end of the sequence.

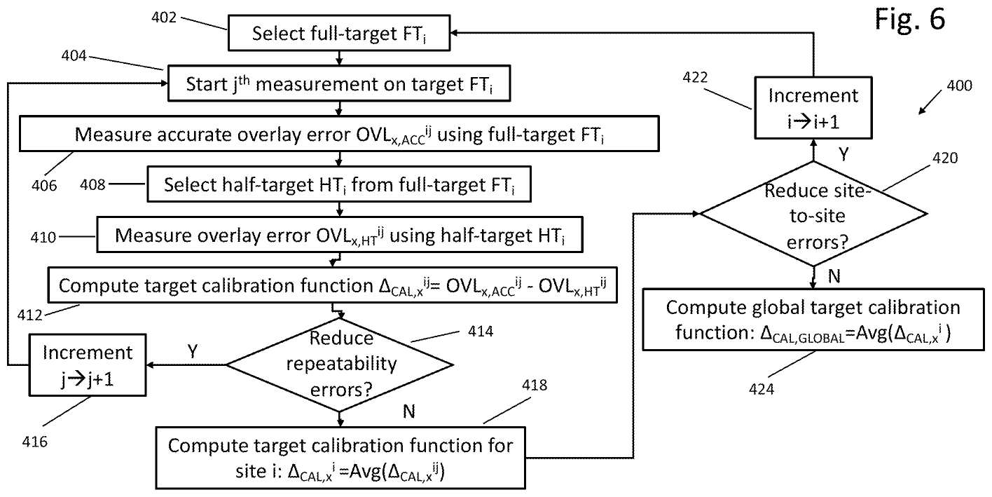

FIG. 6 is flowchart 400 that schematically illustrates a method for determining a target calibration function for half-targets for x-overlay error, in accordance with an embodiment of the invention. The method is carried out, by way of example, by controller 18, using images captured by apparatus 10. In addition to the determination of the target calibration function, as described hereinabove, flowchart 400 also comprises steps for improving the repeatability of the target calibration function (reducing measurement-to-measurement variations) and for mitigating for target-to-target variations. For the sake of brevity, flowchart 400 shows overlay error measurements and calibration only in the x-direction. Measurements and calibration in the y-direction are carried out in similar fashion, as explained above.

In a full target selection step 402, controller 18 selects a full target FTᵢ for the calibration process, wherein i is an index used to enumerate full targets for a multi-target calibration (reduction of target-to-target variations). In a measurement start step 404, a j^{th} measurement of full target FTⁱ is started (j is an index used to enumerate repeated measurements of a given target for improving measurement repeatability).

In a measurement step 406, controller 18 measures an accurate x-overlay error OVL_{x,ACC}^{ij} based on the measurement initiated at step 404. This step, as well as the subsequent steps in flowchart 400, is similar to the calibration technique described above for full target 300 in FIG. 5A. (Superscripts i and j refer to the indices i and j.) In a half-target selection step 408, a half-target included in full target FTᵢ is selected. In a half-target overlay error measurement step 410, overlay error OVL_{x,HT}^{ij} is measured for the selected half-target. In a first target calibration function step 412, target calibration function Δ_{CAL,x}ⁱ) is computed as Δ_{CAL,x}^{ij}=OVL_{x,ACC}^{ij}−OVL_{x,HT}^{ij}, as explained above.

In a first decision step 414, controller 18 decides whether to repeat the measurements on full target FTᵢ for increased repeatability. This decision may be taken by controller 18 either by computing the repeatability from the first j measurements or by using a preset count for the number of measurements. If the measurement is to be repeated, the index j is incremented in a first incrementation step 416, and the process returns to step 404. When no additional measurements of full target FTⁱ are required, the process continues to a second target calibration function step 418, wherein the acquired target calibration functions ΔA_{CAL,x}^{ij} for full target FTᵢ are averaged to give the value Δ_{CAL,x}ⁱ for full target i.

The process continues to a second decision step 420, wherein controller 18 decides whether to include additional full targets in the calibration process in order to mitigate target-to-target variations. The decision in step 420 may be taken by controller 18 either by estimating the target-to-target variation from the first i full targets, by using a preset count for the number of full targets to be included, or by using a preset list of full targets on semiconductor substrate 12. When additional full targets are to be included, the process continues to a second incrementation step 422, where the index i is incremented, and the process returns to step 402. When additional full targets are not required, the target calibration functions Δ_{CAL,x}¹ acquired from the included full targets FTᵢ are averaged to give a global target calibration function Δ_{CAL,GLOBAL}. This function is used for calibrating the x-overlay error measurements for all of the half-targets on the semiconductor substrate that are identical to the one included in the calibration process.

### Calibrating for Angular Misalignment of a Half-Target

As explained above in reference to FIG. 4, an angular misalignment of a half-target, such as half-targets 100 (FIG. 2A) and 200 (FIG. 3A), may lead to an appreciable error in the overlay error measurement. A global angular misalignment α_{GLOBAL} of all half-targets, such as an angular error of semiconductor substrate 12 due to yaw of table 20, may be calibrated using the methods described above for calibration using full targets. (The term “yaw” is used to denote an angular misalignment of table 20 around the normal to the table, and may be measured using, for example, laser interferometers.)

Moving substrate 12 with table 20 from measurement site to measurement site, in order to bring each half-target in its turn into the FOV of objective lens 22, may introduce site-to-site variations in the angular misalignment. An angular misalignment aj may be measured for each half-target HT: either by a yaw measurement for each overlay error measurement site or by suitable processing of the captured target image. For example, controller 18 may define two suitably positioned ROIs on the same grating of a half-target, measure the shift between the two projections of the grating bars from the two ROIs, and compute the angular misalignment by dividing the shift by the center-to-center distance between the ROIs. Index i is used here to enumerate the measured half-targets.

When a target calibration function has been determined using full targets, as has been described hereinabove (FIGS. 5A-5B and FIG. 6), a differential local correction Δ_{DIFF}ⁱ for the target calibration function may be computed as Δ_{DIFF}ⁱ=(αᵢ−α_{GLOBAL})×D, wherein D refers to an appropriate ROI-to-ROI distance, similar to D_{ROI,y} (FIG. 4).

Alternatively, in the absence of such a target calibration function, the measured angular misalignment αⁱ may be applied directly as a local correction Δ_{LOCAL}ⁱ=αᵢ×D. Further alternatively, the angular misalignment αᵢ may be compensated for by an appropriate rotation of table 20 or sensor 28, or a rotation of the captured target image by controller 18.

It will be appreciated that the embodiments described above are cited by way of example, and that the present invention is not limited to what has been particularly shown and described hereinabove. Rather, the scope of the present invention includes both combinations and subcombinations of the various features described hereinabove, as well as variations and modifications thereof which would occur to persons skilled in the art upon reading the foregoing description and which are not disclosed in the prior art.

1. A method for semiconductor metrology, comprising:
depositing a first film layer on a semiconductor substrate and a second film layer overlying the first film layer;
patterning the first and second film layers to define:
first overlay target disposed in a first location on the semiconductor substrate and comprising a first target feature formed in the first film layer and a second target feature formed in the second film layer in a position adjacent to the first target feature; and
a second overlay target disposed in a second location on the semiconductor substrate and comprising a first part, which is identical to the first overlay target, and a second part, which is disposed adjacent to the first part such that the second overlay target has rotational symmetry of 180° around a normal to the semiconductor substrate;
capturing a first image, using an imaging assembly, of the second overlay target;
processing the first image to compute a target calibration function based on both the first and second parts of the second overlay target;
capturing a second image, using the imaging assembly, of the first overlay target; and
processing the second image while applying the target calibration function to estimate an overlay error between patterning of the first and second film layers at the first location.

2. The method according to claim 1, wherein the second part of the second overlay target comprises a rotated copy of the first part.

3. The method according to claim 1, wherein the first overlay target is one of a plurality of first overlay targets, each comprising the first and second target features, disposed at different, respective locations on the semiconductor substrate, and
wherein processing the second image comprises applying the target calibration function to each of the first overlay targets.

4. The method according to claim 1, wherein processing the first image comprises:
using both the first and second parts of the second overlay target in the first image to estimate a first overlay error between the patterning of the first and second film layers;
using only the first part of the second overlay target to estimate a second overlay error between the patterning of the first and second film layers; and
computing the target calibration function responsively to a difference between the first and the second overlay errors.

5. The method according to claim 4, wherein using both the first and second parts comprises estimating the first overlay error by finding a displacement between respective first centers of symmetry of the first target features and the second target features in both the first and second parts of the second overlay target, and
wherein using only the first part comprises estimating the second overlay error by finding a displacement between respective second centers of symmetry of the first target features and the second target features in only the first part of the second overlay target.

6. The method according to claim 1, wherein the first image is captured in a first orientation of the semiconductor substrate, and wherein the method comprises capturing a third image of the second overlay target in a second orientation of the semiconductor substrate, which is rotated by 180° about the normal to the semiconductor substrate relative to the first orientation, and
wherein processing the first image comprises processing both the first and third images to estimate respective first and second overlay errors in the first and second orientations, and computing the target calibration function based on the first and second overlay errors.

7. The method according to claim 1, wherein n the semiconductor substrate comprises dies separated by scribe lines, and wherein the first overlay target is disposed in a device area of a die and the second overlay target is disposed in one of the scribe lines.

8. The method according to claim 1, wherein the first target feature comprises a first linear grating oriented along a first direction in the first film layer, and the second target feature comprises a second linear grating oriented in the first direction in the second film layer.

9. The method according to claim 8, wherein the first target feature further comprises a third linear grating oriented along a second direction, which is not parallel with the first direction, in the first film layer, and the second target feature comprises a fourth linear grating oriented in the second direction in the second film layer.

10. The method according to claim 1, further comprising measuring an angular misalignment of the semiconductor substrate, wherein applying the target calibration function comprises correcting for the angular misalignment in estimating the overlay error.

11. The method according to claim 10, wherein the first overlay target is one of a plurality of the first overlay targets disposed at different, respective locations on the semiconductor substrate, and wherein measuring the angular misalignment comprises estimating and compensating for a local angular misalignment at each of the different locations.

12. A product, comprising:
a semiconductor substrate; and
first and second film layers, which are disposed on the semiconductor substrate with the second film layer overlying the first film layer, and that are patterned to define:
a first overlay target disposed in a first location on the semiconductor substrate and comprising a first target feature formed in the first film layer and a second target feature formed in the second film layer in a position adjacent to the first target feature; and
a second overlay target disposed in a second location on the semiconductor substrate and comprising a first part, which is identical to the first overlay target, and a second part, which is disposed adjacent to the first part such that the second overlay target has rotational symmetry of 180° around a normal to the semiconductor substrate.

13. The product according to claim 12, wherein the second part of the second overlay target comprises a rotated copy of the first part.

14. The product according to claim 12, wherein the first overlay target is one of a plurality of the first overlay targets, each comprising the first and second target features, disposed at different, respective locations on the semiconductor substrate.

15. The product according to claim 12, wherein the semiconductor substrate comprises dies separated by scribe lines, and wherein the first overlay target is disposed in a device area of a die and the second overlay target is disposed in one of the scribe lines.

16. The product according to claim 12, wherein the first target feature comprises a first linear grating oriented along a first direction in the first film layer, and the second target feature comprises a second linear grating oriented in the first direction in the second film layer.

17. The product according to claim 16, wherein the first target feature further comprises a third linear grating oriented along a second direction, which is not parallel with the first direction, in the first film layer, and the second target feature comprises a fourth linear grating oriented in the second direction in the second film layer.

18. Apparatus for semiconductor metrology, comprising:
an imaging assembly, which is configured to capture images of a semiconductor substrate on which first and second film layers are disposed, with the second film layer overlying the first film layer, and that are patterned to define:
a first overlay target disposed in a first location on the semiconductor substrate and comprising a first target feature formed in the first film layer and a second target feature formed in the second film layer in a position adjacent to the first target feature; and
a second overlay target disposed in a second location on the semiconductor substrate and comprising a first part, which is identical to the first overlay target, and a second part, which is disposed adjacent to the first part such that the second overlay target has rotational symmetry of 180° around a normal to the semiconductor substrate; and
a processor, which is configured to process a first image captured by the imaging assembly of the second overlay target to compute a target calibration function based on both the first and second parts of the second overlay target, and to process a second image captured by the imaging assembly of the first overlay target while applying the target calibration function to estimate an overlay error between patterning of the first and second film layers at the first location.

19. The apparatus according to claim 18, wherein the first overlay target is one of a plurality of the first overlay targets, each comprising the first and second target features, disposed at different, respective locations on the semiconductor substrate, and
wherein the processor is configured to apply the target calibration function to each of the first overlay targets.

20. The apparatus according to claim 18, wherein the processor is configured to use both the first and second parts of the second overlay target in the first image to estimate a first overlay error between the patterning of the first and second film layers, and to use only the first part of the second overlay target to estimate a second overlay error between the patterning of the first and second film layers, and to compute the target calibration function responsively to a difference between the first and the second overlay errors.

21. The apparatus according to claim 20, wherein the processor is configured to estimate the first overlay error by finding a displacement between respective first centers of symmetry of the first target features and the second target features in both the first and second parts of the second overlay target, and to estimate the second overlay error by finding a displacement between respective second centers of symmetry of the first target features and the second target features in only the first part of the second overlay target.

22. The apparatus according to claim 18, wherein the imaging assembly is configured to capture the first image in a first orientation of the semiconductor substrate, and to capture a third image of the second overlay target in a second orientation of the semiconductor substrate, which is rotated by 180° about the normal to the semiconductor substrate relative to the first orientation, and
wherein the processor is configured to process both the first and third images to estimate respective first and second overlay errors in the first and second orientations, and computing the target calibration function based on the first and second overlay errors.

23. The apparatus according to claim 18, wherein the processor is configured to measure an angular misalignment of the semiconductor substrate, and to correct for the angular misalignment in estimating the overlay error.

24. The apparatus according to claim 23, wherein the first overlay target is one of a plurality of the first overlay targets disposed at different, respective locations on the semiconductor substrate, and wherein the processor is configured to estimate and compensate for a local angular misalignment at each of the different locations.
